(19) United States
(12) Patent Application Publication
(10) Pub. No.: US 2013/0083591 A1
(43) Pub. Date: Apr. 4, 2013

(54) Alternating Wordline Connection in 8T Cells for Improving Resiliency to Multi-Bit SER Upsets

(71) Applicants: John J. Wuu, Fort Collins, CO (US); Don R. Weiss, Fort Collins, CO (US); Kathryn E. Wilcox, Boylston, MA (US); Alex W. Schaefer, Austin, TX (US); Kerrie V. Underhill, Bolton, MA (US)

(72) Inventors: John J. Wuu, Fort Collins, CO (US); Don R. Weiss, Fort Collins, CO (US); Kathryn E. Wilcox, Boylston, MA (US); Alex W. Schaefer, Austin, TX (US); Kerrie V. Underhill, Bolton, MA (US)

(21) Appl. No.: 13/248,699

(22) Filed: Sep. 29, 2011

(51) Int. Cl. G11C 11/00

(52) U.S. Cl. 365/154

(57) ABSTRACT

An integrated circuit memory is disclosed in which an array of 8 T SRAM cells is arranged in rows and columns using a plurality of write wordlines for each row of 8 T SRAM cells to control write access to cells in the row associated with a first parity/ECC word and a second write wordline operable to control write access to cells in the row associated with a second parity/ECC word.

### BACKGROUND OF THE INVENTION

1. Field of the Invention

The present invention relates in general to integrated circuit memory devices. In one aspect, the present invention relates to a multi-bit error tolerant memory device, and related systems and methods for operating.

2. Description of the Related Art

As integrated circuit designs continue to scale and shrink, memory systems are increasingly vulnerable to reliability and yield problems, including soft and hard errors in the memory system. For example, lower supply voltages and smaller feature sizes decrease the charge stored per cell, making it easier for a soft error to flip a bit and increasing the soft error rate (SER). And as scaling progresses, single error events are more likely to cause large-scale multi-bit errors.

To protect against soft errors, memory designs will include error detection and correction systems, such as error correcting code (ECC) and parity bit schemes. A basic configuration would protect a row of adjacent memory cells (e.g., AAAAAAAA) by adding one or more parity or ECC bits at the end of the row (e.g. AAAAAAAAX), but these codes (ECC or parity) have a limited ability to detect or correct multiple bit errors in the same word of adjacent memory cells. Various solutions attempt to address these limitations by grouping neighboring bits into different parity/ECC words so as to interleave different cells to provide physical separation between cells belonging to the same ECC or parity word. Multi-bit errors are then less likely to upset more cells in a word than the code (ECC or parity) can handle. For example, if the row of eight cells above can be arranged as ABABABAB (“A” and “B” are bits belonging to different parity/ECC words), this effectively introduces a 1-cell separation between bits from the same parity/ECC word so that a double-bit error affecting 2 neighboring bits will only produce single-bit errors on 2 different parity/ECC words. The downside to this approach is the additional overhead required for having the different parity/ECC words. For example, standard Hamming ECC code for 256 b data words would require 10 extra bits. However, the code for 2 separate 128 b data words would require 18 extra bits (9 bits per 128 b word). One way to get around the extra overhead is by employing a column interleaved layout, but as technology continues to shrink, it is increasingly difficult to keep enough separation between cells through column interleaving. Worse, in certain designs, such as 8 T cells whose write ports are not read stable, (i.e., no conditions exist to make the write port operate as a read/write port), traditional column interleaving cannot be implemented without increasing the bitcell size (requiring more space) or requiring writeback/restore of the unselected columns (sacrificing performance, speed, and power consumption).

### SUMMARY OF EMBODIMENTS OF THE DISCLOSURE

Broadly speaking, the present disclosure describes a multi-bit error tolerant memory and method of operation in which a plurality of write wordlines are used for each row of bitcells to alternatively connect to bitcells, thereby allowing neighboring bitcells to be connected to different wordlines so that bits from the same parity/ECC word may be separated by multiple bitcells to improve SER performance. Where the memory is constructed with an array of 8 T cells, parallel write wordlines are deployed for each row of bitcells to alternately connect to the bitcells so that neighboring bitcells belong to different parity words. In this configuration, when a wordline is enabled, the write access ports of alternating bitcell pairs in the selected row are not accessed or disturbed. Therefore, columns can effectively be interleaved without having to write-back the unselected columns, and the physical space between bitcells from the same parity word can be increased. In selected embodiments where neighboring bits from different words (e.g., A, B, C, D) are broken into different parity/ECC words, the neighboring bits (e.g., AB) may be configured to share the same write wordline via an that the 2 bits' write wordlines cannot be enabled independently. In this configuration, the two words (ABABABAB and CDCDCDCD) can be interleaved by the parallel wordlines to provide 3-bit separation between bits from the same parity/ECC word (e.g., ABCDABCD ABCDABCD), thereby improving SER performance without using traditional column interleaving or a read-stable 8 T cell.

In selected example embodiments, an integrated circuit static random access memory system and method of operation are disclosed. The memory system includes an array of SRAM cells arranged in rows and columns. In selected embodiments, each cell in the array is an 8 T SRAM cell which includes a memory unit formed with two cross-coupled inverters for storing data at one or more internal nodes. Each 8 T SRAM cell also includes first and second data access devices coupled to the memory unit for controlling write access to the memory unit from a pair of external nodes under control of one of the plurality of write wordlines supplied to the 8 T SRAM cell. In addition, each 8 T SRAM cell includes a read port device connected between the one or more internal nodes and the read bitline supplied to the 81 SRAM cell to enable data to be read from the memory unit under control of a read wordline supplied to the 8 T SRAM cell, where the read port device comprises a read transistor and a read driver transistor. To access the SRAM array, the memory system also includes a plurality of write wordlines associated with a first row, including a first write wordline operable to control write access to cells in the first row associated with a first word and a second write wordline operable to control write access to cells in the first row associated with a second word. In selected embodiments, a first write wordline is connected to a first plurality of alternating cells in the first row and a second write wordline is connected to a second plurality of alternating cells in the first row such that neighboring cells in the first row are each connected to a different write wordline. In other embodiments, the first write wordline is connected to a first plurality of alternating paired cells in the first row and the second write wordline is connected to a second plurality of alternating paired cells in the first row such that neighboring paired cells in the first row are each connected to a different write wordline. In this way, the first write wordline may be connected to a plurality of cells in the first row associated with a first parity or ECC word, and the second write wordline may be connected to a plurality of cells in the first row associated with a second parity or ECC word. In addition, a read wordline is associated with the first row that is operable to control read access to cells in the first row, one or more write bitlines are associated with each cell in the first row to provide input to said cell during write operations, and a read bitline is associated with each cell in the first row to receive output from said cell during read operations. As fabricated, the plurality of write wordlines and the read wordline may be formed in one or more metal interconnect layers, depending on whether there is space available for two write wordline conductors on a layer.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a schematic diagram of an 8 T cell having an isolated read port;

FIG. 2 shows a simplified schematic diagram of a first exemplary array of memory cells having alternating write wordlines in each row of cells in accordance with selected embodiments of the present disclosure;

FIG. 3 shows a simplified schematic diagram of a second exemplary array of memory cells having alternating write wordlines in each row of cells in accordance with selected embodiments of the present disclosure; and

FIGS. 4a-4c are plan views of exemplary physical layouts of metal layer conductors for connecting alternating wordlines to a pair of mirrored 8 T cells in accordance with selected embodiments of the present disclosure.

### DETAILED DESCRIPTION

A memory circuit design, architecture, and method of operation are described having at least two write wordlines for each row of bitcells in a memory array to alternately connect bitcells in the row so that neighboring bitcells may be connected to different write wordlines to separate bitcells from the same parity/ECC word by a plurality of bitcells in selected embodiments, one of a pair of write wordlines is connected to every other bitcell in the row, while the other write wordline from the pair of write wordlines is connected to the remaining bitcells in the row. In other embodiments, a first write wordline from a pair of write wordlines is connected to a first pair of mirrored cells in a row, the second write wordline from the pair of write wordlines is connected to the next (second) pair of mirrored cells in the row, the first write wordline is connected to a next (third) pair of mirrored cells in the row, and so on. In this configuration, when the first wordline is enabled to access alternating pairs of mirrored cells in the row, the write access ports of remaining bitcell pairs in the selected row are not accessed (or disturbed) to effectively interleave columns without having to write-back the unselected columns, and the physical space between bitcells from the same parity word can be increased. To construct the memory circuit as an integrated circuit, the dedicated write wordlines for each bitcell row may be formed in the same metal layer (e.g., M3) as parallel conductors if there is sufficient space for two write wordline tracks. If there is not adequate space, the dedicated write wordlines may be formed in a plurality of upper metal interconnect layers (e.g., M4 and above) to alternately align the relevant write wordline conductor with the underlying write wordline conductors for the cell.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected embodiments of the present invention are implemented, for the most part, with electronic components and circuits known to those skilled in the art, and as a result, circuit details have not been explained in any greater extent since such details are well known and not considered necessary to teach one skilled in the art of how to make or use the present invention. In addition, selected aspects are depicted with reference to simplified circuit schematic diagrams and block diagram drawings without including every circuit detail or feature in order to avoid limiting or obscuring the present invention. Such descriptions and representations are used by those skilled in the art to describe and convey the substance of their work to others skilled in the art.

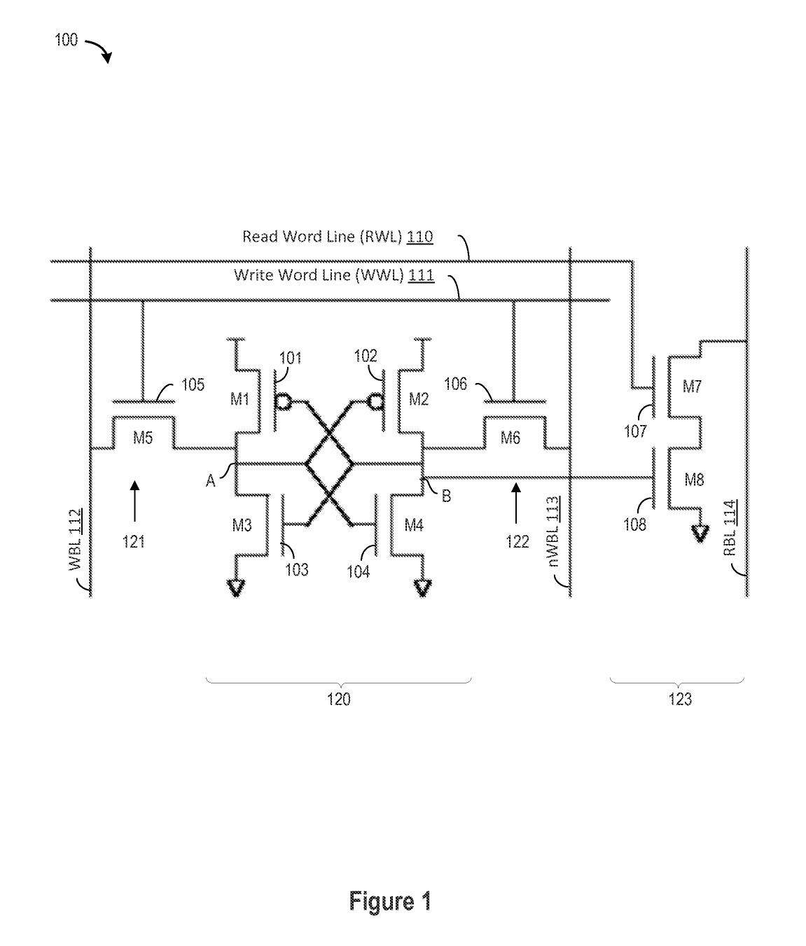

Referring now to FIG. 1, there is shown a simplified schematic diagram of an 8 T static random access memory (SRAM) cell 100 having an isolated read port. The depicted SRAM cell 100 includes a six transistor memory unit 120 and a pair of access devices 121, 122 for connecting the memory unit 120 to a pair of write bitlines 112, 113. The memory unit 120 may be formed with two cross-coupled inverters M1/M3 and M2/M4, where each inverter is formed from an NMOS and PMOS transistor pair connected in series and cross coupled to the other inverter to enable the memory unit to store data at internal nodes A, B. The access devices 121, 122 may each be formed with an access transistor M5, M6 for controlling write access to the memory unit nodes A, B via the write wordline (WWL) 111. As depicted, a first write access transistor 105 is connected to the first memory unit output at internal node A, and a complementary second write access transistor 106 is connected to the second memory unit output at internal node B. The gates of the first and second write transistors 105, 106 are each connected to a write wordline (WWL) 111, thereby forming a write circuit that is used to impose a state on the SRAM cell 100 in cooperation with the WWL 111, a write bit-line (WBL) 112 and a complementary write bit-line (nWBL) 113. For example, if the WBL 112 is set to a “high” value (e.g., Vdd) while the nWBL 113 is set to “low” value (e.g., Vss), then, when the WWL 111 is asserted (set to Vdd), the output of the first inverter M1/M3 will be set to a value of Vdd plus the drain-source voltage of load transistor M1, while the output of the second inverter M2/M4 will be set to Vss plus the drain-source voltage of driver transistor M4. This state may be interpreted as a logical “one” for the SRAM cell core 100. Conversely, by repeating this operation with the WBL 112 set to Vss and the nWBL 113 set to Vdd, the SRAM core cell 100 would be set to a logical “zero.”

To read the state of the memory cell 100, a read circuit 123 is provided as a read port or buffer that is attached to the memory unit 120 and serves as a read port or buffer. The read circuit 123 may include a read transistor M7 107 and a read driver transistor M8 108. As depicted, the gate of the read driver transistor 108 is connected to the memory unit output at internal node B, though it will be appreciated that it could instead be connected to the memory unit output at internal node A. A source of the read transistor 107 is connected to a drain of the read driver transistor 108, and a drain of the read transistor 107 is connected to a read bitline (RBL) 114. The gate of the read transistor 107 is connected to the read wordline (RWL) 110, while the gate of the write access transistors 105, 106 are connected to the write wordline (WWL) 111. As a result, the write access transistors 105, 106 transistors and the read transistor 107 are controlled by separate wordline selection signals. The use of individual wordlines for the READ and WRITE operations permits customized READ and WRITE operation voltages that avoids a trade-off between a fast (higher voltage, higher current) read access and a stable write (lower voltage write) that avoids data upsets in a memory device comprising SRAM cell 100, white permitting a compact cell layout.

Those skilled in the art will appreciate that other memory cell configurations and access circuits could be used, including using additional or fewer transistors, as well as using complementary transistor polarities and/or control signals. For example, the memory cell could be implemented as a 6 T SRAM or 10 T SRAM cell, or could be implemented with dynamic random access (DRAM) cell designs. However, in selected low voltage applications, the 8 T bitcell shown in FIG. 1 provides an improved read static-noise margin (SNM) (to avoid bit flipping) and read current (to avoid sensing failures due to bitline leakage). With an 8 T cell, the read ports still leak, but the read current can be increased without sacrificing cell stability, provided that the read port is sized to obtain the desired read current and meet speed targets. Another advantage of 8 T cells is cell sizes can be chosen to make writes occur more rapidly since there is no trade off required for with read stability.

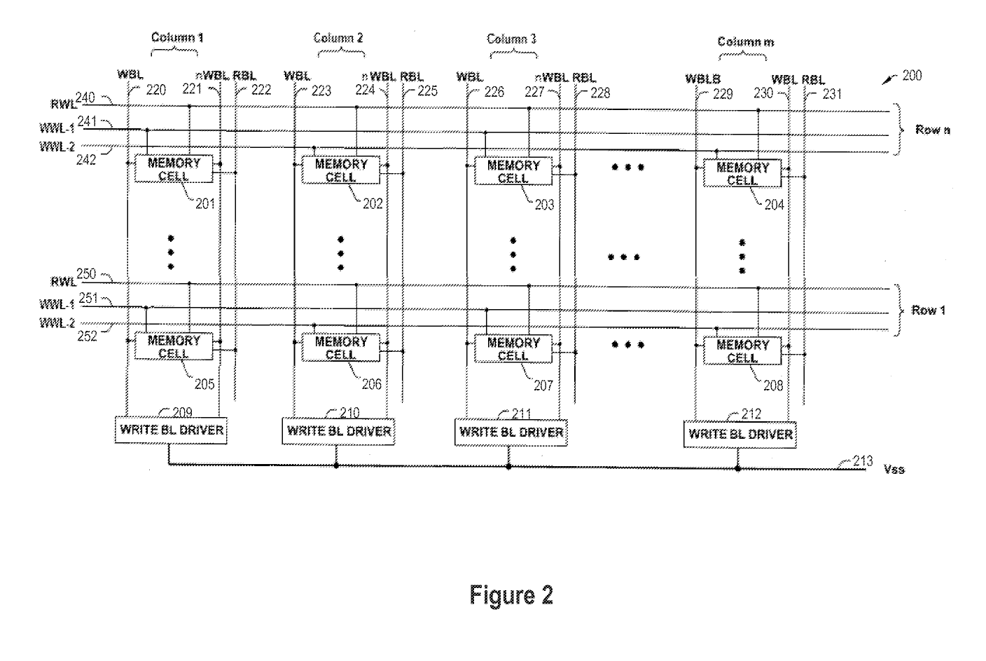

Turning now to FIG. 2, there is illustrated a simplified schematic diagram of a first exemplary array 200 of memory cells 201-208 having alternating write wordlines in each row of cells in accordance with selected embodiments of the present disclosure. As depicted, the memory cells 201-208 are arranged in rows 1-n and columns 1-m such that the arrayed memory cells are connected to columns of read and write bitlines, and to rows of read and write wordlines. For example, the cells 201, 205 in Column 1 are connected to pair of write bitlines (WBL 220, nWBL 221) and a read bitline (RBL 222). Likewise, the cells 202, 206 in Column 2 are connected to pair of write bitlines (WBL 223, nWBL 224) and a read bitline (RBL 225), and so on through Column m. In addition, the cells 201-204 in Row n are connected to a read wordline (RWL 240) and are also alternately connected to a pair of write wordlines (WWL-1 241, WWL-2 242) such that one of the wordlines 241 is connected to alternating cells (e.g. 201, 203, etc.), while the other wordline 242 is connected to the other cells (e.g., 202, 204, etc.). In similar fashion, the cells 205-208 in Row 1 are connected to a read wordline (RWL 250) and are also alternately connected to a pair of write wordlines (WWL-1 251, WWL-2 252), and so on.

In operation, the write bitlines in a column (e.g., 220, 221) are driven with complimentary states by a write bitline driver for that column (e.g., 209) during memory write operations. In similar fashion, the write bitlines column 2 (e.g., 222, 224) are driven by a write bitline driver 210, the write bitlines in column 3 (e.g., 226, 227) are driven by a write bitline driver 211, and the write bitlines in column m (e.g., 229, 230) are driven by a write bitline driver 212. With reference to the a memory cell 201 implemented with the 8 T cell example depicted in FIG. 1, the gate of the read transistor M7 107 is connected to a read wordline RWL 240 for row n for controlling access to the cells 201-204 in row n during a read operation, and the drain of the read transistor M7 107 is connected to a read bit line RBL 222 associated with column 1 during a read operation,

In the example array 200, the write wordlines along each row (e.g., row n) are connected to the cells (e.g., 201-204) such that neighboring cells belong to different parity words. For example, a first parity word (AAAAAAAA) may be stored in odd numbered bitcells in a row (e.g., 201, 203, etc.) that are connected to a first write wordline WWL-1 241, while a second parity word (BBBBBBBB) is stored in even numbered bitcells in the row (e.g., 202, 204, etc.) that are connected to a second write wordline WWL-2 242. With this arrangement, the two parity words may be physically arranged for storage in row n as ABABABABABABABAB, thereby providing the benefits of column multiplexing in that there is a one cell separation between bits from the same parity word. However, the alternating write wordline arrangement allows data to be written into the first parity word (AAAAAAAA) without destroying data in the second parity word (BBBBBBBB) and without requiring a write-back/restore procedure. In addition, the alternating write wordline configuration does not require read-stable cells (since writing into AAAAAAAA doesn't disturb BBBBBBBB), so the array 200 may be implemented with 8 T SRAM cells 201-208. Another benefit of using the alternating write wordline configuration is that two parity/ECC words can be stored without requiring additional parity/ECC bits.

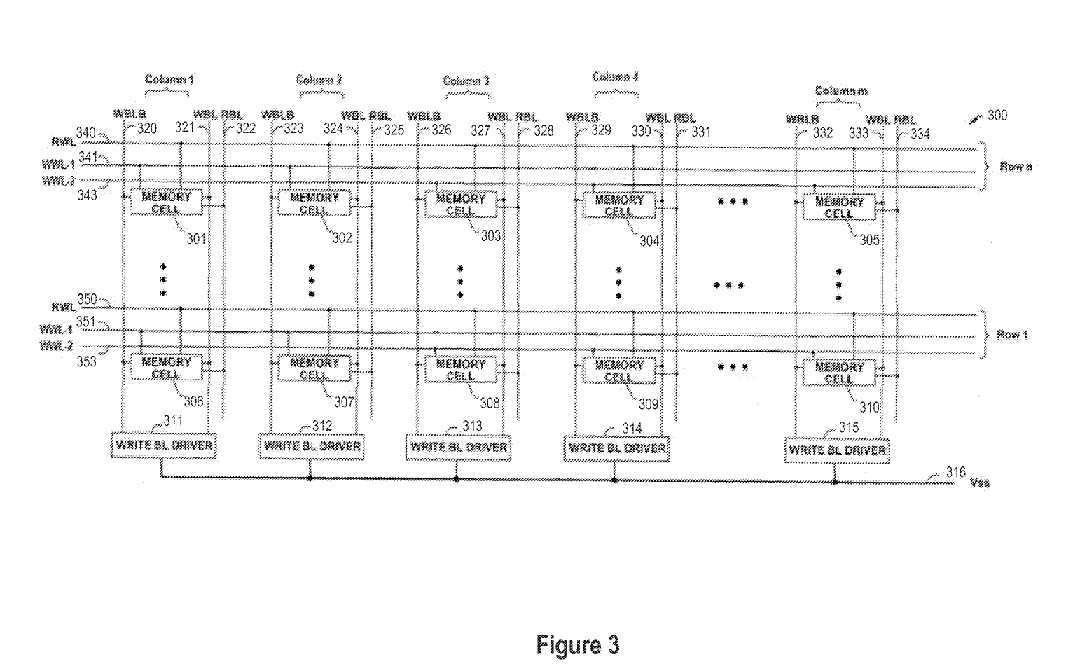

While there are advantages from obtaining single cell separation between bits of two parity words, the distance can be increased using the alternating write wordlines to further improve resiliency against multi-bit SER events. For example, FIG. 3 shows a simplified schematic diagram of a second exemplary array 300 of memory cells 301-310 arranged in rows 1-n and columns 1-m wherein four or more parity/ECC words are stored in a single row, thereby providing at least a three cell separation between bits from the same parity/ECC word. As depicted, the arrayed memory cells 301-310 are connected to columns of read bitlines 322, 328, 331, 334 and write bitlines 320-321, 323-324, 326-327, 329-330, 332-333. In addition, the memory cells 301-310 are connected to rows of read wordlines 340, 350 and write wordlines 341-342, 351-352. However, instead of connecting each write wordline to every other memory cell (as shown in FIG. 2), the first write wordline in a row (e.g., WWL-1 341) is connected to a first pair of memory cells (e.g., 301, 302) and the second write wordline in the row (e.g., WWL-2 342) is connected to next pair of memory cells (e.g., 303, 304), and so on.

With this arrangement, each pair of memory cells in a row may be used to store bits from different parity/ECC words. Thus, bits A₁ and B₁ from first and second parity/ECC words A₁A₂ A₃ A₄ A₅ A₆ A₇A₈ and B₁B₂ B₃ B₄ B₅ B₆ B₇B₈ could be stored, respectively, in cells 301, 302 which share the same write wordline WWL-1 341 such that the cells 301, 302 cannot be enabled independently. In addition, bits C₁ and D₁ from third and fourth parity/ECC words C₁C₂ C₃ C₄ C₅ C₆ C₇C₈ and D₁D₂ D₃ D₄ D₅ D₆ D₇D₈ could be stored, respectively, in cells 303, 304 which share the same write wordline WWL-2 342. With the alternating write wordline configuration, the two words A₁B₁A₂B₂A₃B₃A₄B₄ and C₁D₁C₂D₂C₃D₃C₄D₄ can be interleaved in a single row A₁B₁C₁D₁A₂B₂C₂D₂ A₃B₃C₃D₃A₄B₄C₄D₄, thereby providing 3-bit separation between bits from the same parity/ECC word.

During read operations, the read bitline e.g., 325) in the column for the accessed memory cell (e.g., 302) storing a bit (e.g., B₁) for the desired parity/ECC word is connected to the memory cell by activation of the read wordline (e.g., 340) for the accessed memory cell. Simultaneously, the read bitlines in the columns which store the other bits (e.g., B₂B₃B₄B₅B₆B₇B₈) for the desired parity/ECC word (e.g., column 6, column 10, column 14, etc.) are also connected to their corresponding memory cells by activation of the corresponding read wordlines (not shown). In this way, the entirety of the desired parity/ECC word (B₁B₂B₃B₄B₅B₆B₇B₈) is read from the array 300,

And when writing a selected parity/ECC word (e.g., B₁B₂ B₃B₄B₅B₆B₇B₈), the write bitlines (e.g., 323, 324) in the columns which store the bits for the selected parity/ECC word (e.g., column 2, column 6, column 10, column 14, etc.) are driven with complimentary states by a corresponding write bitline driver for each column (e.g., 312). In addition, the write bitlines are connected to the memory cells for the selected parity/ECC word by activating the corresponding write wordline (e.g., 341), even though this also connects the paired memory cells.

The disclosed alternating wordline configuration may also be used with other interleaving schemes. For example, if there are two parity words (AAAAAAAA and BBBBBBBB), these parity words can be interleaved as AABBAABBAABBAABB. In this way, one write wordline connects to all the A parity word bits and the other connects to all the B parity word bits.

As seen from the foregoing, by alternately connecting a plurality of write wordlines to the cells in a row (e.g., cells 301-305 in row n), multi-cell separation may be obtained between bits from a given parity/ECC word, thereby improving resilience to multi-bit SER upsets without requiring the overhead associated with conventional column interleaving. In selected embodiments where two parallel write wordlines are provided for each row of bitcells, the parallel write wordlines alternately connect to the write access transistors in alternating cells so that neighboring bitcells are connected to different write wordlines. In other embodiments where two neighboring bitcells that share vias to the access transistors are used to store bits from different parity words, the neighboring bitcells are connected to the same write wordline, while the next pair of bitcells is connected to the second wordline. With the alternating bitcell pair configuration, a first write wordline enables the write access ports to a first bitcell pair, but does not enable or disturb the write access ports of alternating Med(pairs in the selected row. Therefore, columns can effectively be interleaved without having to write-back the unselected columns, and the physical space between bitcells from the same parity word can be increased.

In schemes such as shown in FIG. 3 where each write-WL connects to a pair of bitcells, selected embodiments of the present invention may be applied in architectures where bitcell pairs belong to different parity/ECC words. However, selected embodiments may also be employed with other architectures. For example, if different ECC codes that can tolerate double bit errors were used (e.g. DECTED code, which stands for Double-Error-Correct, Triple-Error-Detect), then the bitcell pairs would not need to belong to different ECC words. Also, certain products may deem double-bit errors acceptable (under standard Hamming SECDED code, double-bit errors would be detectable but not correctable), and this would allow bitcell pairs to belong to the same ECC word.

To fabricate an integrated circuit memory array as described herein, the plurality of write wordlines for each bitcell row may be formed in the same metal layer (e.g., M3) as the read wordline if there is sufficient space for two write wordline tracks. But given the relatively tight spacing constraints for a memory cell, there may not be adequate space to fit two alternating wordline tracks in a single metal interconnect layer. With such constraints, the plurality of write wordlines for each row may be formed in one or more upper metal interconnect layers to alternately align the relevant write wordline conductor with the underlying write wordline conductors for the cell.

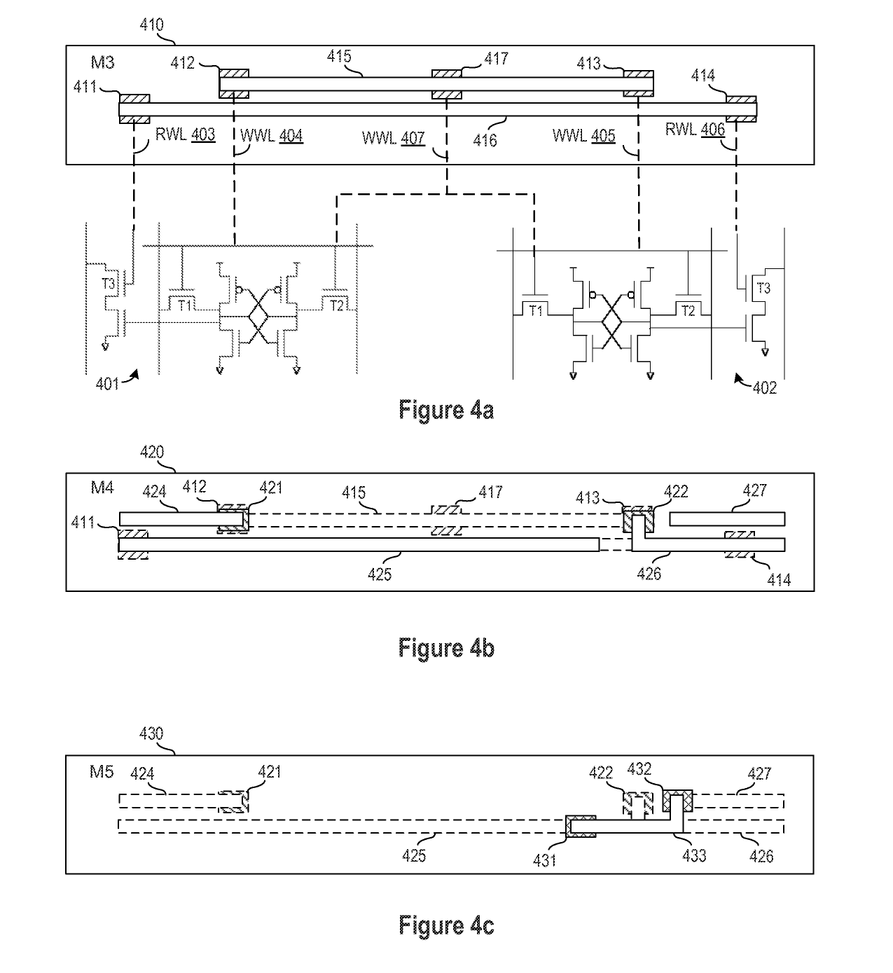

An example implementation of a multi-layer, multi-write wordline structure is shown in FIGS. 4a-4c which depicts plan views of exemplary physical layouts of metal layer conductors for connecting alternating wordlines to a pair of mirrored 8 T cells using an alternating wordline scheme in accordance with selected embodiments of the present disclosure. For clarity, the relevant metal layer conductors for the write wordlines are shown in solid outline, the underlying vias are shown with cross-hatching for the relevant layer metal interconnect layer, and the underlying layers are shown with gray-scale lines for purposes of demonstrating alignment between different metal interconnect layers. As will be appreciated, the particular layout and/or shape of the wordlines can follow standard design familiar to those skilled in the art of integrated circuit design. As will be appreciated, the interlayer dielectric layers (ILDs) are not shown separately.

In FIG. 4a, there is depicted a plan view of an exemplary physical layout 410 of a metal interconnect layer (e.g., M3) in which a write wordline conductor 415 and read wordline conductor 416 are formed in parallel alignment with the write wordline conductor 415 pulled back from the edges of the cell area. To illustrate how the write wordline conductor 415 and read wordline conductor 416 are connected to a pair of mirrored cells 401, 402 formed in the integrated circuit below the metal interconnect layers, FIG. 4a shows a simplified schematic of a pair of mirrored cells 401, 402. As depicted, the write access transistors T1, T2 in the first cell 401 are gated by the write wordline 404 which is connected through via 412 to the write wordline conductor 415, while the read transistor T3 in the first cell 401 is gated b the read wordline 403 which is connected through via 411 to the read wordline conductor 416. In selected embodiments, the write access transistors T2 in the first cell 401 may also be gated by the shared write wordline 407 which is connected through shared via 417 to the write wordline conductor 415, where the shared via 417 is positioned at the shared edges of the mirrored cells 401, 402 to be shared there between. In similar fashion, the write access transistors T1, T2 in the second cell 402 are gated by the write wordline 405 (and optionally write wordline 407) which is connected through via 413 (and shared via 417) to the write wordline conductor 415, while the read transistor T3 in the second cell 402 is gated by the read wordline 406 which is connected through via 414 to the read wordline conductor 416. In the plan view 410, it can be seen that the write wordline conductor 415 and read wordline conductor 416 may be formed in the metal interconnect layer, but there are not enough conductor tracks to tit an additional write wordline conductor.

When there is inadequate space on the first metal interconnect layer for two write wordlines, one or more additional metal interconnect layers may be used to help route the pair of write wordlines as part of an alternating wordline scheme. In selected embodiments, parallel write wordline conductors could be routed back and forth on the next metal interconnect layer to alternately make contact with the write wordline conductor 415. But if there is not enough space in the next metal interconnect layer for parallel write word additional layers could be used for alternating write wordlines on the layer(s) above the actual write wordline. For example, FIG. 4b depicts a plan view of an exemplary physical layout 420 of a second metal interconnect layer (e.g., M4) in which two write wordline conductors are run to alternately connect to the write wordline conductor 415 in the first metal interconnect layer. As depicted, a first wordline is formed with first and second conductor lines 424, 426 which are connected to the underlying write wordline conductor 415 through vias 421, 422, respectively. In addition, the second wordline is formed with third and fourth conductor lines 425, 427. In 4 first track, the first conductor line 424 from the first write wordline is positioned and connected through via 421 to the underlying write wordline conductor 415. In a parallel track, the third conductor line 425 from the second write wordline is formed but is not connected to the underlying read wordline conductor 416. While the shape and positioning of the first conductor line 424 aligns with the track of the underlying write wordline conductor 415 in the first metal interconnect layer, the shape and positioning of the second conductor line 426 effectively switches the track positioning for the first wordline with the second wordline. As a consequence, the fourth conductor line 427 from the second write wordline is positioned in alignment with the first track.

To route the pair of write wordlines as part of an alternating wordline scheme, an additional metal interconnect layer may be used to connect the third and fourth conductor lines 425, 427 of the second write wordline. For example, FIG. 4c depicts a plan view of an exemplary physical layout 430 of a third metal interconnect layer (e.g., M5) in which a conductor line 433 connects to the third and fourth conductor lines 425, 427 to form the second write wordline. As depicted, the conductor line 433 is connected to the underlying third and fourth conductor lines 425, 427 through vias 431, 432 respectively. In addition, the shape and positioning of the conductor line 433 effectively swizzles the second write wordline so that it is aligned in the track with the write wordline conductor 415 of the first metal interconnect layer.

FIGS. 4a-c represent simplified layout embodiments of the present invention for implementing an alternating wordline scheme in three metal interconnect layers to help alternately route two write wordlines through vias down to the M3 write wordline track, but it will be appreciated that additional or fewer metal interconnect layers can be used, depending on the available area at each layer. In selected embodiments, the alternating wordline routing is achieved at the M4 metal interconnect layer by forming parallel write wordline conductors that are routed back and forth in the M4 interconnect layer to alternately make aligned contact with the M3 write wordline track. This arrangement preserves M5 tracks for other uses, and should also have fewer speed and yield implications that would otherwise be implicated by the extra vias and swizzling to the M5 layer.

As memory cell sizes continue to shrink, resulting in memory devices which use lower supply voltages Vdd and smaller gate capacitances, the smaller critical charge stored at each memory cell means that the soft-error rate (SER) is expected to be increase significantly since the upset charge remains the same, resulting in higher multi-bit upset soft error rates. The disclosed arrangement of alternating a plurality of write wordlines to each row of memory cells provides a multi-bit error tolerant memory which effectively provides the benefits of column interleaving to increase the physical separation between memory cells belonging to the same ECC/parity word, but without incurring the penalty associated with column interleaving 8 T cells having write ports that are not read stable. Another benefit of interleaving multiple ECC/parity words onto a single memory cell row with alternating write wordlines is the reduced area overhead required to process multiple ECC/parity words stored on a row with multiple write wordlines as compared to a single ECC/parity word stored in the row with a single write wordline. Though described herein with reference to exemplary 8 T memory cell embodiments, it will be appreciated that the disclosed multi-bit error tolerant memory does not require the use of 8 T cells with read-stable write ports.

By now it will be appreciated that there is disclosed herein a method and integrated circuit device for storing data. In the disclosed method and device, an array of SRAM bitcells (e.g., 8 T SRAM memory cells) are provided that are arranged in rows and columns. In the array, first and second write wordlines are provided for each row alternately connected, respectively, to a first plurality of bitcells and a second plurality of bitcells in the row so that neighboring bitcells are connected to different write wordlines. In selected embodiments, the first write wordline for each row is connected to every other bitcell in the row, thereby defining the first plurality of bitcells, and the second write wordline for the row is connected to the remaining bitcells in the row, thereby defining the second plurality of bitcells, so that neighboring bitcells are connected to different write wordlines. In other embodiments, the first write wordline for each row is connected to every other pair of bitcells in the row, thereby defining the first plurality of bitcells, and the second write wordline for the row is connected to the remaining pairs of bitcells in the row, thereby defining the second plurality of bitcells, so that neighboring bitcells are connected to different write wordlines. In addition, a read wordline is provided for each row connected to the first and second plurality of bitcells in the row. Access for write operations to a first plurality of bitcells in each row is controlled using the first write wordline for the row which is connected to the first plurality of bitcells in the row. In addition, access for write operations to a second plurality of bitcells in each row is controlled using the second write wordline for the row which is connected to the second plurality of bitcells in the row. As for read operations, access to the first and second plurality of bitcells in each row is controlled using the read wordline for the row. With this arrangement, first and second parity or ECC words may be stored in a selected row of the array of SRAM bitcells with the first parity/ECC word being stored in the first plurality of bitcells of the selected row and with the second parity/ECC word being stored in the second plurality of bitcells of the selected row.

In another form, there is provided an integrated circuit static random access memory (SRAM) and method for manufacturing same. As disclosed, the SRAM includes an array of SRAM cells formed in a substrate and arranged in rows and columns. In addition, first and second write wordlines are formed for each row over the substrate in at least a first metal layer and alternately connected, respectively, to a first plurality of bitcells and a second plurality of bitcells in the row so that neighboring bitcells are connected to different write wordlines. There is also a read wordline formed for each row over the substrate in at least the first metal layer and connected to the first and second plurality of bitcells in the row. In selected embodiments, the first and second write wordlines and the read wordline for each row are formed in the first metal layer. However, in other embodiments, they are formed in different metal layers. For example, the first write wordline for a row may be formed with a first conductor line formed in a first track of the first metal layer over the first plurality of bitcells. In addition, the first write wordline includes a second conductor line formed in the first track of a second metal layer extending from the first plurality of bitcells to the second plurality of bitcells to overlap and make contact with the first conductor line. The first write wordline also includes a third conductor line formed in the first track of the second metal layer over the first plurality of bitcells to overlap and make contact with the first conductor line, extending from the first track to a second track of the second metal layer, and extending from the first plurality of bitcells to the second plurality of bitcells in the second track of the second metal layer. Finally, the first write wordline includes a fourth conductor line formed in the second track of a third metal layer over the second plurality of bitcells to overlap and make contact with the third conductor line, extending from the second track to the first track of the third metal layer, and extending from the second plurality of bitcells to the first plurality of bitcells in the first track of the third metal layer.

Although the described exemplary embodiments disclosed herein are directed to selected stacked die embodiments and methods for fabricating same, the present invention is not necessarily limited to the example embodiments which illustrate inventive aspects of the present invention that are applicable to a wide variety of memory types, processes and/or designs. For example, other such cell and transistor technologies may be used. In addition, the present disclosure is not confined to the fabrication of silicon wafers, but may be implemented in association with the manufacture of various semiconductor devices, SRAM memory devices, or other such devices, wherein the design and optimization of an SRAM cell, potential data upsets, error correction, error detection, and/or power consumption is an issue. Thus, the particular embodiments disclosed above are illustrative only and should not be taken as limitations upon the present invention, as the invention may be modified and practiced in different but equivalent manners apparent to those skilled in the art having the benefit of the teachings herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

Accordingly, the particular embodiments disclosed above are illustrative only and should not be taken as limitations upon the present invention, as the invention may be modified and practiced in different but equivalent manners apparent to those skilled in the art having the benefit of the teachings herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

What is claimed is:

1. A static random access memory (SRAM), comprising:
an array of SRAM cells arranged in rows and columns; and
a plurality of write wordlines associated with a first row comprising a first write wordline operable to control write access to one or more first cells in the first row associated with a first word and a second write wordline operable to control write access to one or more second cells in the first row associated with a second word, thereby interleaving the first cells and second cells in the first row.

2. The SRAM of claim 1, further comprising:
a read wordline associated with the first row that is operable to control read access to cells in the first row;
one or more write bitlines associated with each cell in the first row to provide input to during write operations; and
a read bitline associated with each cell in the first row to receive output from said cell during read operations.

3. The SRAM of claim 1, where each SRAM cell comprises an 8 T SRAM memory cell comprising:
a memory unit comprising two cross-coupled inverters for storing data at one or more internal nodes;
first and second data access devices coupled to the memory unit for controlling write access to the memory unit from a pair of external nodes under control of one of the plurality of write wordlines supplied to the 8 T SRAM cell; and
a read port device connected between the one or more internal nodes and the read bitline supplied to the 8 T SRAM cell to enable data to be read from the memory unit under control of a read wordline supplied to the 8 T SRAM cell, where the read port device comprises a read transistor and a read driver transistor.

4. The SRAM of claim 1, where the plurality of write wordlines comprises a first write wordline connected to a first plurality of alternating cells in the first row and a second write wordline connected to a second plurality of alternating cells in the first row such that neighboring cells in the first row are each connected to a different write wordline.

5. The SRAM of claim 1, where the plurality of write wordlines comprises a first write wordline connected to a first plurality of alternating paired cells in the first row and a second write wordline connected to a second plurality of alternating paired cells in the first row such that neighboring paired cells in the first row are each connected to a different write wordline.

6. The SRAM of claim 1, where the plurality of write wordlines comprises:
a first write wordline connected to a plurality of cells in the first row associated with a first parity word; and
a second write wordline connected to a plurality of cells in the first row associated with a second parity word.

7. The SRAM of claim 1, where the plurality of write wordlines comprises:
a first write wordline connected to a plurality of cells in the first row associated with a first error correcting code (ECC) word; and
a second write wordline connected to a plurality of cells in the first row associated with a second ECC word.

8. The SRAM of claim 1, where the plurality of write wordlines and the read wordline are formed in a single metal interconnect layer.

9. The SRAM of claim 1, where the plurality of write wordlines and the read wordline are formed in a plurality of metal interconnect layers,

10. A method of storing data in an integrated circuit, comprising:
providing an array of SRAM bitcells arranged in rows and columns with first and second write wordlines for each row alternately connected, respectively, to a first plurality of bitcells and a second plurality of bitcells in the row so that neighboring bitcells are connected to different write wordlines, and with a read wordline for each row connected to the first and second plurality of bitcells in the row;
controlling access for write operations to a first plurality of bitcells in each row using the first write wordline for the row which is connected to the first plurality of bitcells in the row;
controlling access for write operations to a second plurality of bitcells in each row using the second write wordline for the row which is connected to the second plurality of bitcells in the row; and
controlling access for read operations to the first and second plurality of bitcells in each row using the read wordline for the row.

11. The method of claim 10, further comprising storing first and second parity words in a selected row of the array of SRAM bitcells with the first parity word being stored in the first plurality of bitcells of the selected row and with the second parity word being stored in the second plurality of bitcells of the selected row.

12. The method of claim 10, further comprising storing first and second ECC words in a selected row of the array of SRAM bitcells with the first ECC word being stored in the first plurality of bitcells of the selected row and with the second ECC word being stored in the second plurality of bitcells of the selected row.

13. The method of claim 10, where the first write wordline for each row is connected to every other bitcell in the row, thereby defining the first plurality of bitcells, and where the second write wordline for the row is connected to the remaining bitcells in the row, thereby defining the second plurality of bitcells, so that neighboring bitcells are connected to different write wordlines.

14. The method of claim 10, where the first write wordline for each row is connected to every other pair of bitcells in the row, thereby defining the first plurality of bitcells, and where the second write wordline for the row is connected to the remaining pairs of bitcells in the row, thereby defining the second plurality of bitcells, so that neighboring bitcells are connected to different write wordlines.

15. The method of claim 10, where the array of SRAM bitcells comprises an array of 8 T SRAM memory cells.

16. The method of claim 10, where the first and second write wordlines and the read wordline for each row are formed in a single metal interconnect layer.

17. The method of claim 10, where the first and second write wordlines and the read wordline for each row are formed in a plurality of metal interconnect layers.

18. An integrated circuit static random access memory (SRAM) comprising:
an array of SRAM cells formed in a substrate and arranged in rows and columns;
first and second write wordlines formed for each row over the substrate in at least a first metal layer and alternately connected, respectively, to a first plurality of bitcells and a second plurality of bitcells in the row so that neighboring bitcells are connected to different write wordlines; and
a read wordline formed for each row over the substrate in at least the first metal layer and connected to the first and second plurality of bitcells in the row,

19. The integrated circuit of claim 18, where the first and second write wordlines and the read wordline for each row are formed in the first metal layer.

20. The integrated circuit of claim 18, where the first write wordline for a row comprises:
a first conductor line formed in a first track of the first metal layer over the first plurality of bitcells;
a second conductor line formed in the first track of a second metal layer extending from the first plurality of bitcells to the second plurality of bitcells to overlap and make contact with the first conductor line;
a third conductor line formed in the first track of the second metal layer over the first plurality of bitcells to overlap and make contact with the first conductor line, extending from the first track to a second track of the second metal layer, and extending from the first plurality of bitcells to the second plurality of bitcells in the second track of the second metal layer; and
a fourth conductor line formed in the second track of a third metal layer over the second plurality of bitcells to overlap and make contact with the third conductor line, extending from the second track to the first track of the third metal layer, and extending from the second plurality of bitcells to the first plurality of bitcells in the first track of the third metal layer.
